(19) United States
(12) Patent Application Publication
(10) Pub. No.: US 2019/0377002 A1
(43) Pub. Date: Dec. 12, 2019

(54) PROBE CARD INCLUDING STRAIGHT NEEDLE HAVING ADJUSTABLE CONTACT FORCE

(71) Applicant: TEPS CO., LTD., Hwaseong-si, Gyeonggi-do (KR)

(72) Inventors: Jaebok LEE, Hwaseong-si, Gyeonggi-do (KR); Deokha HWANG, Hwaseong-si, Gyeonggi-do (KR)

(73) Assignee: TEPS CO., LTD., Hwaseong-si, Gyeonggi-do (KR)

(21) Appl. No.: 16/464,477

(22) PCT Filed: Dec. 27, 2017
(86) PCT No.: PCT/KR2017/015567

§ 371 Date: May 28, 2019

(30) Foreign Application Priority Data
Dec. 27, 2016 (KR) 10-2016-0179676

(51) Int. Cl. G01R 1/073

(52) U.S. Cl. CPC G01R 1/07314

(57) ABSTRACT

Disclosed is a needle probe card including: a first plate having a plurality of needle holes into which straight needles are inserted and installed to face a test object; a second plate having a plurality of needle holes into which the straight needles are inserted and installed above the first plate so as to be relatively movable in a first direction with respect to the first plate; a needle drop prevention plate having a plurality of needle holes into which the straight needles are inserted and installed between the first plate and the second plate so as to be relatively movable in the first direction with respect to each of the first plate and the second plate; and a displacement amount adjustment means configured to adjust a relative displacement amount among the first plate, the second plate, and the needle drop prevention plate in the first direction.

### CROSS-REFERENCE TO PRIOR APPLICATIONS

This application is a National Stage Patent Application of PCT International Patent Application No. PCT/KR2017/015567 filed on Dec. 27, 2017 under 35 U.S.C. § 371, which claims priority to Korean Patent Application No. 10-2016-0179676 filed on Dec. 27, 2016, which are all hereby incorporated by reference in their entirety.

### BACKGROUND

The present invention relates to a straight needle probe card, and more particularly, to a probe card capable of easily adjusting a contact force of a straight needle.

In order to reduce packaging costs, a plurality of semiconductor devices (for example, a dynamic random access memory (DRAM), a NAND flash memory, or the like.) formed on a semiconductor wafer are subjected to a pass/fail test at a wafer level before being diced and packaged for each semiconductor device. To this end, a probe card is used to transfer test signals from a semiconductor tester to pads of the semiconductor devices on the wafer. Specifically, the probe card includes probe pins in the form of a needle, and the probe needles come into contact with the pads of the semiconductor devices on the wafer so that the test signals from the semiconductor tester are applied to the pads of the semiconductor devices. At this point, in order to ensure contacts between the probe needles and the pads of the semiconductor devices, the probe needles come into contact with the pads of the semiconductor devices with certain contact forces, which inevitably causes damages to the pads.

The pads on the wafer with which the probe needles of the probe card come into contact are generally aluminum (Al) pads, but strengths of the pads differ according to a grain size of aluminum crystal or alloying elements. Particularly, in recent years, pads of various shapes and materials such as bumps for wafer level chip scale packaging (WLCSP) and copper pillars have been used instead of the Al-pads. In order to minimize the damages of the pads on the wafer by the probe needles, the contact forces with which the probe needles come into contact with the pads have to be changed according to the shape and material of the pads on the wafer.

To this end, in a conventional probe card, contact forces of probe needles are adjusted by changing the structure of the needles. However, since different needles of the complicated structure such as pogo needles, cantilever needles, and buckling needles have to be used depending on types of wafers to be tested, the different needles have to be developed for each wafer characteristic, and there is also difficulty in inventory management of the probe needles.

Particularly, when buckling needles such as cobra needles are used in a vertical probe card, there is a limitation in reducing pitches due to a needle structure, and it is troublesome that plates of the probe card have to be disassembled when replacing needles broken during use.

### SUMMARY

The present invention has been made in view of the above-mentioned problems, and specifically, the objective of the present invention is to provide a probe card, in particular, a probe card using a straight needle, capable of easily adjusting a contact force without changing the structure of the needle itself.

According to an aspect of the present invention, provided is a probe card including a first plate having a plurality of needle holes into which straight needles are inserted and installed to face a test object, a second plate having a plurality of needle holes into which the straight needles are inserted and installed above the first plate so as to be relatively movable in a first direction with respect to the first plate, a needle drop prevention plate having a plurality of needle holes into which the straight needles are inserted and installed between the first plate and the second plate so as to be relatively movable in the first direction with respect to each of the first plate and the second plate, and a displacement amount adjustment means configured to adjust a relative displacement amount among the first plate, the second plate, and the needle drop prevention plate in the first direction.

According to a probe card of the present invention, the degree of bending (curvature) of a straight needle can be adjusted so that a contact force of the needle can be adjusted without changing the structure of the needle by adjusting a displacement amount when displacing a second plate and a needle drop prevention plate in a first direction with respect to the first plate in a state in which the straight needle is inserted. Accordingly, the contact force of the probe needle, which is optimized for a wafer to be tested, can be applied according to the wafer type (such as copper (Cu)-pillar, wafer level chip scale packaging (WLCSP), and aluminum (Al) pad) and characteristics. Further, since the straight needle having a simple structure can be used as it is, a defect rate in manufacturing the needle can be lowered, manufacturing costs can be reduced, and a needle insertion process and replacement of a broken needle can be facilitated. Further, since pitches between the needles can be reduced, it is advantageous for the production of a fine pitch probe card.

### BRIEF DESCRIPTION OF THE DRAWINGS

FIG. 1 is a cross-sectional view of a probe card according to the present invention.

FIG. 2 is a plan view of each plate constituting the probe card of the present invention.

FIG. 3 is a conceptual diagram for describing adjustment of a relative displacement amount between a second guide plate and a needle drop prevention plate of the present invention.

### DETAILED DESCRIPTION

Hereinafter, embodiments of the present invention will be described in detail with reference to the accompanying drawings. Here, it is noted that specific structural and functional details disclosed herein are described just for the purpose of illustrating the exemplary embodiments only. Accordingly, a probe card described below is for embodying the technical concept of the present invention, and thus the present invention is not limited to the following unless otherwise stated. Further, the contents described in any one embodiment may also be applied to other embodiments. Accordingly, it should be understood that the embodiments may take various modifications and alternative forms and are not intended to limit the embodiments to the specific forms disclosed herein. On the contrary, it should also be understood that the embodiments of the present invention may include all modifications, equivalents, and alternatives falling within the scope of the present invention.

Further, throughout the description of the drawings, like reference numerals refer to like elements.

Further, an expression “and/or” used herein includes anyone of one or more related items and all combinations thereof.

Further, terms used herein are only for describing specific embodiments and do not intend to limit the embodiments. Expressions such as “any”, “a/an”, and “the” used herein should be interpreted to include plural forms unless clearly indicated otherwise in the context.

Further, terms “include” and/or “including” used herein specify the presence of described features, steps, operations, elements, and/or components, and does not preclude the presence or addition of other features, steps, operations, elements, components, and/or groups thereof. It should be understood that terms relating to space include other directions of devices in use or operating in addition to the directions shown in the drawings.

Further, it should be understood that, in some alternative implementations, functions/operations may occur in a different order than described in the drawings. For example, two consecutive drawings may be actually performed simultaneously, or sometimes in reverse order, according to associated functions/operations.

In the present invention, forces with which probe needles come into contact with pads of a wafer may be easily adjusted by precisely adjusting a degree of bending of the needle without changing a structure of a straight needle.

Hereinafter, a structure of a straight needle probe card of the present invention will be described in detail with reference to the drawings.

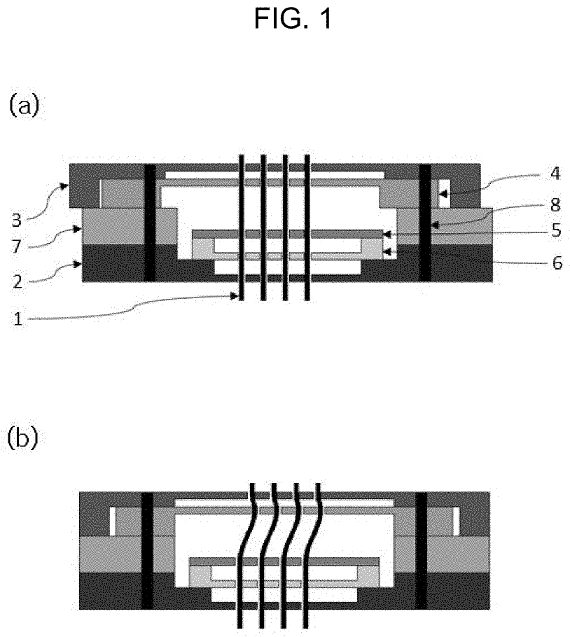

FIG. 1 is a cross-sectional view of the straight needle probe card according to the present invention. The probe card of the present invention includes a first guide plate (first plate) 2 facing a semiconductor wafer which is an object to be tested and formed with a plurality of needle holes 10 into which the straight needles 1 are inserted, a second guide plate (second plate) 3 installed above the first guide plate, having the plurality of needle holes 10, and relatively movable in a bending direction (first direction) of the straight needle with respect to the first guide plate 2, and a needle drop prevention plate 4 installed between the first guide plate 2 and the second guide plate 3 and relatively movable in the first direction with respect to each of the first guide plate 2 and the second guide plate 3.

FIG. 1A illustrates a state in which the needle holes 10 of the first guide plate 2, the second guide plate 3, and the needle drop prevention plate 4 are all concentric with each other, and the straight needles 1 are inserted thereinto, and FIG. 1B illustrates a state in which the second guide plate 3 and the needle drop prevention plate 4 are relatively displaced in the first direction with respect to the first guide plate 2.

As the second guide plate 3 and the needle drop prevention plate 4 are relatively displaced with respect to the first guide plate 2, the straight needles 1 are bent as shown in FIG. 1B, and as will be described below, the degree of bending of the straight needle may be adjusted by adjusting a relative displacement amount of the second guide plate 3 and the needle drop prevention plate 4, so that contact forces with which the straight needles come into contact with pads, bumps, or the like of the wafer may be adjusted.

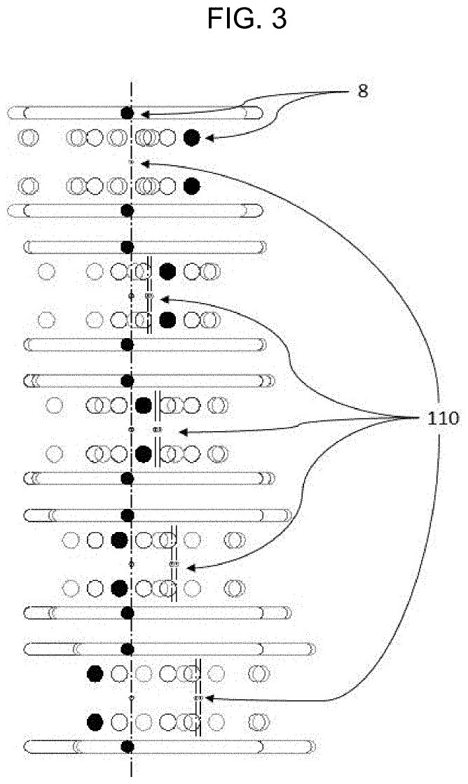

When the plates are relatively displaced in the first direction, the straight needle 1 is brought into contact with an inner wall surface of one side of the needle hole 10 of the needle drop prevention plate 4 with an elastic force by making the relative displacement amount of the needle drop prevention plate 4 with respect to the first guide plate 2 greater than the relative displacement amount of the second guide plate 3 with respect to the first guide plate 2, thereby preventing the needle from being dropped even when the contact force is applied in a direction perpendicular to the plate during the test. This will be described below with reference to FIG. 3.

The probe card according to the present invention may further include an interference prevention guide film 5 and/or a third guide plate 6. The interference prevention guide film 5 prevents the occurrence of interference between the needles caused by the bending of the straight needle in a situation in which lengths of the needles are not uniform. The third guide plate 6 prevents the needles from making inclined contact with the pads, the bumps, or the like of the semiconductor wafer instead of being vertically brought into contact therewith due to the bending of the needles.

Heights of the plates (for example, the first guide plate, the second guide plate, and the like) shown in FIG. 1 may be set differently according to characteristics of the wafer which is an object to be tested. Here, instead of changing the heights of the plates shown in FIG. 1, a separate height adjustment plate 7 may be used, as shown in FIG. 1, without changing the heights of the other plates. Functions and effects of the height adjustment plate 7 will be described below.

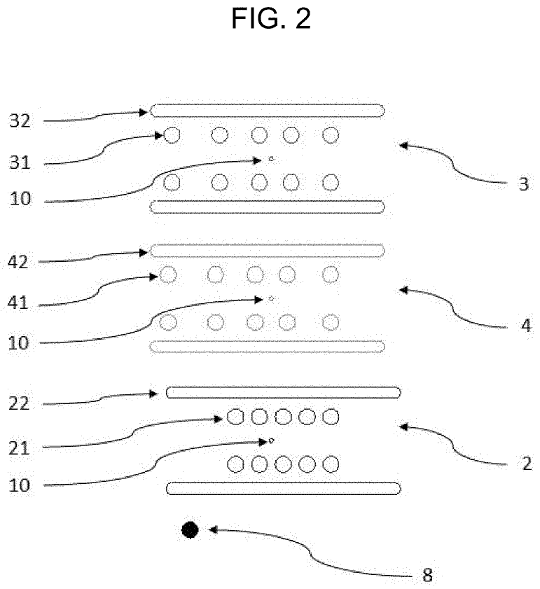

FIG. 2 is a conceptual plan view of the first guide plate 2, the second guide plate 3, and the needle drop prevention plate 4 of the straight needle probe card according to the present invention.

As shown in FIG. 2, the first guide plate 2, the second guide plate 3, and the needle drop prevention plate 4 include the needle hole 10 into which the straight needle is inserted, displacement amount adjustment holes 21, 31, and 41 as a displacement amount adjustment means for adjusting the relative displacement amount between the plates, and displacement direction guide holes 22, 32, and 42 as a guide means for guiding the relative displacements of the plates.

Here, although only one needle hole 10 is shown for the convenience of explanation, a plurality of needle holes are actually formed according to the number of semiconductor devices (devices under test (DUTs)) tested at one time. The needle holes 10 may have different sizes depending on the characteristics of the wafer which is the object to be tested.

The displacement amount adjustment holes 21, 31, and 41 are formed in plural numbers according to the number of displacement distances to be set. When displacement amount adjustment holes positioned at the end among the displacement amount adjustment holes 21, 31, and 41 in the first direction are referred to as first displacement amount adjustment holes 211, 311, and 411, for example, two displacement distances can be set by additionally forming, two displacement amount adjustment holes other than the first displacement amount adjustment holes to have a total of three displacement amount adjustment holes, and four displacement distances can be set by forming a total of five displacement amount adjustment holes. Although the displacement amount adjustment holes 21, 31, and 41 may be formed in one row in the first direction, as shown in FIG. 2, the displacement amount adjustment holes 21, 31, and 41 may be formed in two rows so that each plate may be more stably fixed at a desired position.

The displacement distances of the second guide plate 3 and the needle drop prevention plate are determined by a distance between the displacement amount adjustment holes 31 and 41 of the second guide plate 3 and the needle drop prevention plate and the corresponding displacement amount adjustment hole 21 of the first guide plate 2 in the first direction. For example, relative distances between second displacement amount adjustment holes 212, 312, and 412 of the three plates in the first direction determine a first displacement distance of the second guide plate 3 and the needle drop prevention plate 4 with respect to the first guide plate 2. In this manner, the distances between the displacement amount adjustment holes formed in any one of the plates may be sufficiently secured even when the displacement distances need to be set very finely by forming the displacement amount adjustment holes in each plate in proportion to the number of displacement distances to be set, so that the strength of the plate may be maintained, and the processing of the plate may be simplified.

The first displacement amount adjustment holes 211, 311, and 411 and the needle hole 10 are formed in each plate such that the distances from the first displacement amount adjustment holes 211, 311, and 411 to the needle hole 10 are the same in all the plates. Thus, when the second guide plate 3 and the needle drop prevention plate 4 are relatively displaced so that the first displacement amount adjustment hole 311 of the second guide plate 3 and the first displacement amount adjustment hole 411 of the needle drop prevention plate 4 are concentric with the first displacement amount adjustment hole 211 of the first guide plate 2, as shown in FIG. 1A, all the needle holes formed in all the plates are also concentric with each other, so that the straight needle 1 may be inserted into the needle hole 10. For a needle insertion operation into the needle hole 10, a plate fixing pin 8 (fixing means) is inserted into the first displacement amount adjustment holes 211, 311, and 411 so as to pass therethrough to fix a position of each plate in the first direction.

The displacement amount adjustment holes 21, 31, and 41 are formed in a circular shape, but the shape is not limited thereto, and also, a size thereof is not limited to a specific size.

The guide holes 22, 32, and 42 are to prevent each plate from being displaced in a tilted state in the first direction and make a moving direction of each plate constant when the second guide plate 3 and the needle drop prevention plate 4 are relatively displaced with respect to the first guide plate 2 in the first direction. The guide holes 22, 32, and 42 may be formed in the shape of an elongated hole in the first direction, and two guide holes separated in a direction (second direction) perpendicular to the first direction may be formed to guide the plates more stably, but the present invention is not limited thereto.

In the embodiments of the present invention, the displacement amount adjustment holes 21, 31, and 41 are adopted as the relative displacement amount adjustment means between the plates, and a configuration is adopted in which the fixing pin 8 is inserted into the displacement amount adjustment holes 21, 31, and 41 to fix the positions of the plates in the first direction, but the present invention is not limited thereto, and other mechanical, electrical, and magnetic means may be used as long as the relative displacement amount between the plates in the first direction may be adjusted and the displaced plate may be fixed.

Further, in the embodiments of the present invention, the guide holes, which are long holes having an elongated shape in the first direction, are adopted as a guide means for guiding the relative displacement between the plates, but the present invention is not limited thereto, and other mechanical, electrical, and magnetic guide means may be used as long as the moving directions of the plates may be guided.

Hereinafter, a process of relatively displacing the second guide plate 3 and the needle drop prevention plate 4 with respect to the first guide plate 2 in the first direction to adjust a displacement amount will be described in more detail with reference to FIG. 3.

First, the second guide plate 3 and the needle drop prevention plate 4 are moved in the first direction such that the first displacement amount adjustment holes 311 and 411 of the second guide plate 3 and the needle drop prevention plate 4 are concentric with the first displacement amount adjustment hole 211 of the first guide plate 2, and the fixing pin 8 is inserted into the first displacement amount adjustment holes 211, 311, and 411 which are concentric with each other to fix the positions of the plates in the first direction. Thus, the plurality of needle holes 10 formed in each plate are also vertically concentric with each other, and each of the straight needles 1 is inserted into each needle hole 10.

After the needles 1 are inserted into the needle holes 10, the plate fixing pin 8 is removed from the first displacement amount adjustment holes 211, 311, and 411, and the second guide plate 3 and the needle drop prevention plate 4 are relatively moved with respect to the first guide plate 2 such that the second displacement amount adjustment holes 312 and 412 of the second guide plate 3 and the needle drop prevention plate 4 are concentric with the second displacement amount adjustment hole 212 of the first guide plate 2, and then the fixing pin 8 is inserted into the second displacement amount adjustment holes 212, 312, and 412 to fix the position of each plate in the first direction.

By such relative displacements of the plates, the needle holes 10 of the second guide plate 3 and the needle drop prevention plate 4 are moved to the positions shown by a reference numeral 110 in FIG. 3, so that the straight needles inserted into the needle holes 10 are bent at a curvature determined by the relative displacement amount thereof, as shown in FIG. 1B. In particular, since a distance between the second displacement amount adjustment hole 412 and the first displacement amount adjustment hole 411 of the needle drop prevention plate 4 is longer than a distance between the second displacement amount adjustment hole 312 and the first displacement amount adjustment hole 311 of the second guide plate 3, the bent straight needles are brought into close contact with the inner wall surface (inner wall surface in a direction opposite to the first direction) of the needle holes 10 of the needle drop prevention plate 4 with an elastic force. Further, the straight needles 1 are brought into close contact with inner wall surfaces of the needle holes 10 of the first guide plate 2 and the second guide plate 3 in the first direction with an elastic force. Accordingly, the straight needles are prevented from being dropped.

The curvature at which the straight needle is bent may be changed according to the relative displacement distances of the second guide plate 3 and the needle drop prevention plate 4 with respect to the first guide plate 2 and/or relative positions at which the displacement amount adjustment hole of the second guide plate 3 and the corresponding displacement amount adjustment hole of the needle drop prevention plate 4 are formed, and the contact force between the straight needle and the pad or the bump of the semiconductor wafer changes according to the curvature of a bent section of the straight needle. That is, the greater the displacement amount in the first direction, the greater the curvature of the bent section of the needle and the smaller the contact force with which the needle comes into contact with the pad or bump of the wafer.

Likewise, the relative displacement amount between the plates may be adjusted by relatively moving other displacement amount adjustment holes of the second guide plate 3 and the needle drop prevention plate 4 to be concentric with the corresponding displacement amount adjustment hole of the first guide plate 2, and thus, the curvature of the bent section of the needle and eventually the contact force of the needle, may be adjusted while using the straight needle with a simple structure as it is.

As shown in FIG. 1, the probe card according to the present invention may further include the height adjustment plate 7 between the first guide plate 2 and the second guide plate 3. By changing a height of the height adjustment plate 7 of the probe card according to the structure or characteristics of the wafer to be tested, the curvature of the bent section of the straight needle 1 may be adjusted independently from the adjustment by the relative displacement of the second guide plate 3 and the needle drop prevention plate 4 in the first direction. That is, even when the relative displacement amounts of the second guide plate 3 and the needle drop prevention plate 4 in the first direction are made constant, the curvature of the bent section of the needle may be reduced by increasing the height of the height adjustment plate 7, thereby increasing the contact force of the needle.

The curvature of the straight needle may be controlled more precisely by further including the height adjustment plate 7, and thus, the contact force of the needle may also be adjusted more precisely. Further, the height of the probe card may be set according to the characteristics of the wafer to be tested by adjusting the height of the height adjustment plate 7 instead of changing the heights of all other plates according to the characteristics of the wafer to be tested, and thus, guide plates having different heights do not need to be manufactured according to the characteristics of the wafer to be tested.

Although specific terms have been used to describe the present invention, the specific terms are used in a generic and descriptive sense only and not for purposes of limitation, and thus, should be understood accordingly. Accordingly, it will be understood by those of ordinary skill in the art that various changes in form and details may be made without departing from the spirit and scope of the present invention as set forth in the following claims.

While the present invention has been described above with reference to the exemplary embodiments, it should also be understood that the present invention is not limited to the disclosed exemplary embodiments. Furthermore, it should be apparent that the above-described embodiments may be implemented in combination with each other. The scope of the following claims is to be accorded the broadest interpretation so as to encompass all such modifications and equivalent structures and functions.

1. A straight needle probe card capable of adjusting a contact force of straight needles, the straight needle probe card comprising:
a first plate having a plurality of needle holes into which the straight needles are inserted and installed to face a test object;
a second plate having a plurality of needle holes into which the straight needles are inserted and installed above the first plate so as to be relatively movable in a first direction with respect to the first plate;
a needle drop prevention plate having a plurality of needle holes into which the straight needles are inserted and installed between the first plate and the second plate so as to be relatively movable in the first direction with respect to each of the first plate and the second plate; and
a displacement amount adjustment means configured to adjust a relative displacement amount among the first plate, the second plate, and the needle drop prevention plate in the first direction.

2. The straight needle probe card of claim 1, further comprising a height adjustment plate installed between the first plate and the needle drop prevention plate.

3. The straight needle probe card of claim 1, wherein the displacement amount adjustment means includes a plurality of displacement amount adjustment holes formed in each of the first plate, the second plate, and the needle drop prevention plate in the first direction.

4. The straight needle probe card of claim 3, wherein the displacement amount adjustment holes are formed in two rows in the first direction.

5. The straight needle probe card of claim 1, wherein the first plate, the second plate, and the needle drop prevention plate are formed with a guide means to guide displacements thereof in the first direction.

6. The straight needle probe card of claim 5, wherein the guide means includes guide holes which have an elongated shape in the first direction.

7. The straight needle probe card of claim 6, wherein two guide holes are formed in a second direction perpendicular to the first direction.

8. The straight needle probe card of claim 1, further comprising a fixing means configured to fix positions of the first plate, the second plate, and the needle drop prevention plate in the first direction.

9. The straight needle probe card of claim 1, further comprising an interference prevention guide film having a plurality of needle holes and installed between the needle drop prevention plate and the first plate.

10. The straight needle probe card of claim 9, further comprising a third plate having a plurality of needle holes and installed between the first plate and the interference prevention guide film.

11. A method for adjusting a contact force of straight needles of a straight needle probe card, the method comprising:
inserting the straight needles into a plurality of needle holes formed in a first plate, a second plate, and a needle drop prevention plate;
moving the second plate and the needle drop prevention plate in a first direction according to the contact force that the straight needle needs to have such that one of a plurality of displacement amount adjustment holes, which are formed in the second plate and the needle drop prevention plate, and the corresponding displacement amount adjustment hole of the first plate are concentric with each other; and
inserting a fixing means into the displacement amount adjustment holes of the first plate, the second plate, and the needle drop prevention plate, which are concentric with each other.
